(19) United States
(12) Patent Application Publication
(10) Pub. No.: US 2003/0030827 A1
(43) Pub. Date: Feb. 13, 2003

(54) Image processing apparatus and image forming apparatus

(75) Inventor: Masatsugu Hirayama, Yokohama-shi (JP)

Correspondence Address: Johnny A. Kumar, FOLEY & LARDNER, Washington Harbour, 3000 K Street, N.W., Suite 500, Washington, DC, 20007-5109, US

(73) Assignee: TOSHIBA TEC KABUSHIKI KAISHA

(21) Appl. No.: 09/922,733

(22) Filed: Aug. 7, 2001

(51) Int. Cl. B41J 1/00; G06F 15/00; G03F 3/08

(52) U.S. Cl. 358/1.9; 358/518

(57) ABSTRACT

According to the present invention, a filter size is increased, and the degree of freedom for a filtering process is increased, making it possible to design a filter such that a contrast is enhanced or damped for each finer bandwidth in a frequency region.

In addition, a filter coefficient set stored in a ROM is configured in size that is ¼ of the filter size. Namely, as a method for storing a coefficient of a large filter size, when a filter is divided into four quadrants, symmetry is provided to each coefficient belonging to one of these quadrants such that coincidence is obtained when the adjacent other quadrants are returned. In this manner, data in amount that corresponds to that of one of the above quadrants (including the remaining portion if the filter cannot be divided into four sections), thereby reducing a storage capacity.

### BACKGROUND OF THE INVENTION

1. Field of the Invention

The present invention relates to an image forming apparatus such as a full color copying machine or a color printer.

2. Description of the Related Art

Conventionally, as an image forming apparatus for outputting a color image, there has been well known a so called four-stage tandem full color copying machine using four image forming units that forms a toner image of each of colors such as yellow (Y), magenta (M), cyan (C), and black (K) based on color decomposed image data.

A filtering process is applied to the above image data, whereby advantageous effect of noise elimination or contrast enhancement can be attained. However, in a conventional filter size, there has been a disadvantage that a structure of a manuscript image having its net spot structure cannot be broken or a hardware scale is excessively large if the filter size is increased.

### BRIEF SUMMARY OF THE INVENTION

It is an object of the present invention to provide an image processing apparatus in which, since filter coefficients mainly used has isotropy at all the sides relevant to target pixels, only one of the filter coefficients divided into four sections relevant to a filter size is provided as hardware, these coefficients are symmetrically used for target data during copying operation, and the hardware scale is reduced, whereby a filtering process can be carried out; and an image forming apparatus having the image processing apparatus.

That is, it is an object of the present invention to provide an image processing apparatus capable of providing an effect of noise elimination or contrast enhancement without excessively increasing a hardware scale, and further, capable of breaking a structure of a manuscript image having its net spot structure; and an image forming apparatus having the image processing apparatus.

According to the present invention, there is provided an image processing apparatus comprising:

a color converting section that converts three primary colors of colors supplied for each pixel of a manuscript image into plural types of color data related to a complementary color;

a region identifying section that identifies a region for each pixel based on the three primary colors of the colors supplied for each pixel of the manuscript image;

a setting section that sets a value of sharpness setting;

a storage section that stores a filter coefficient that consists of a basic coefficient and a differential coefficient for each value of sharpness setting;

a generating section that reads out from the storage section the filter coefficient based on the value of the setting caused by the setting section, and generates plural types of matrix shaped filters, each of which corresponds to an area identified by the region identifying section according to the read out filter coefficient;

a selecting section that selects one of the plural types of matrix shaped filters generated by the generating section according to the identification result from the region identifying section; and

a filter section that subjects color data acquired from the color converting section to a filtering process by using the matrix shaped filter selected by the selecting section.

An image processing method of such type comprises the steps of:

converting three primary colors of colors supplied for each pixel of a manuscript image into plural types of color data related to a complementary color;

identifying a region for each pixel based on the three primary colors of the colors supplied for each pixel of the manuscript image;

reading out the filter coefficient based on the value of sharpness setting based on the filter coefficient that consists of a basic coefficient and differential coefficient for each value of sharpness setting stored in the storage section; and

generating plural types of matrix shaped filters, each of which corresponds to an area identified by the region identifying section according to the read out filter coefficient;

selecting one of the plural types of matrix shaped filters generated by the generating section; and

subjecting color data acquired from the color converting section to a filtering process by using the matrix shaped filter selected by the selecting section.

According to the present invention, there is provided an image forming apparatus comprising:

image readout means for reading three primary colors of colors for each pixel of a manuscript image;

a color converting section that converts the three primary colors of colors read out by the image readout means into plural types of color data related to complementary colors;

a region identifying section that identifies a region of each pixel based on the three primary colors of the colors supplied for each pixel of the manuscript image;

a setting section that sets a value of sharpness setting;

a storage section that stores a filter coefficient that consists of a basic coefficient and a differential coefficient for each value of sharpness setting;

a generating section that reads out from the storage section a filter coefficient based on the value of setting caused by the setting section, and generates plural types of matrix shaped filters that corresponds to a region identified by the region identifying section according to the read out filter coefficient;

a selecting section that selects one of plural types of matrix shaped filters generated by the generating section according to the identification result from the region identifying section;

a filter section that subjects color data acquired from the color converting section to a filtering process by using the matrix shaped filter selected by the selecting section; and

image forming means for forming an image on a medium formed image thereon based on color data outputted from the filter section.

Additional objects and advantages of the invention will be set forth in the description which follows, and in part will be obvious from the description, or may be learned by practice of the invention. The objects and advantages of the invention may be realized and obtained by the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiment of the invention, and together with the general description given above and the detailed description of the preferred embodiment given below, serve to explain the principles of the invention.

FIG. 1 and FIG. 2 is a block diagram schematically depicting an internal configuration of a digital color copying machine according to one embodiment of the present invention;

FIG. 3 is a block diagram depicting a schematic configuration of a filter processing section;

FIG. 4 is a block diagram depicting a schematic configuration of a computing section;

FIG. 5 is a view showing a filter configuration;

FIG. 6 is a view showing a filter coefficient example;

FIG. 7 is a view illustrating a difference in frequency characteristics due to a difference in filter size;

FIG. 8 is a view showing a filter coefficient example;

FIG. 9 is a view showing an image data example that corresponds to the filter coefficient example; and

FIG. 10 is a view illustrating frequency characteristics of a filter according to sharpness adjustment values.

### DETAILED DESCRIPTION OF THE INVENTION

Hereinafter, an image forming apparatus such as a digital color copying machine according to embodiments of the present invention will be described with reference to the accompanying drawings.

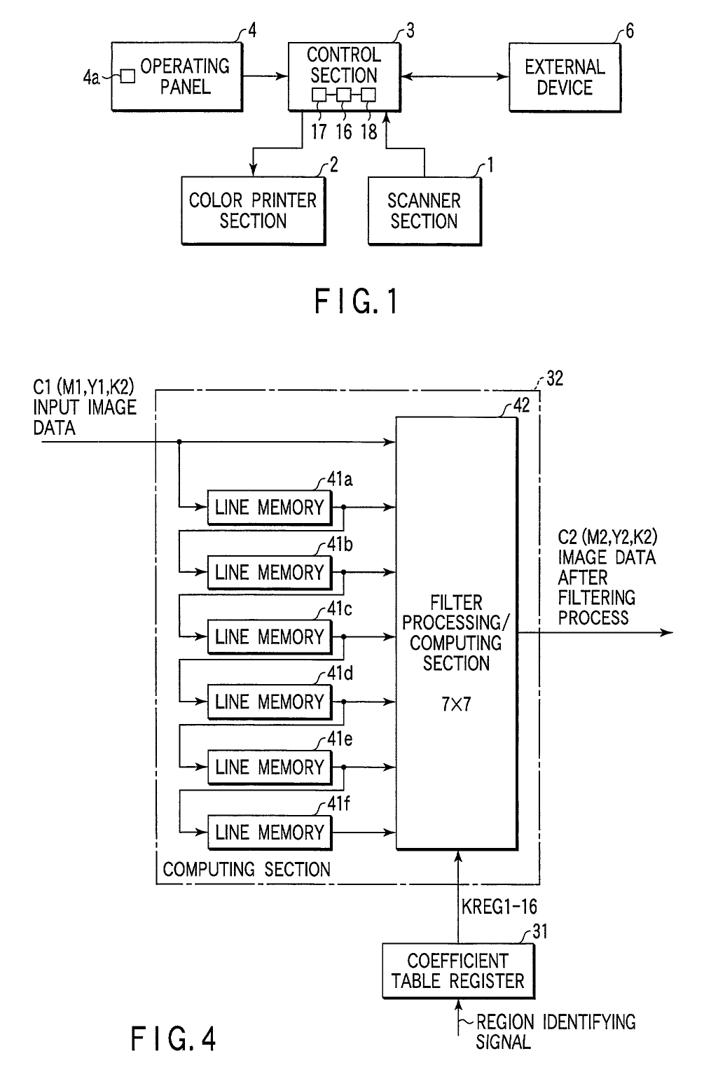

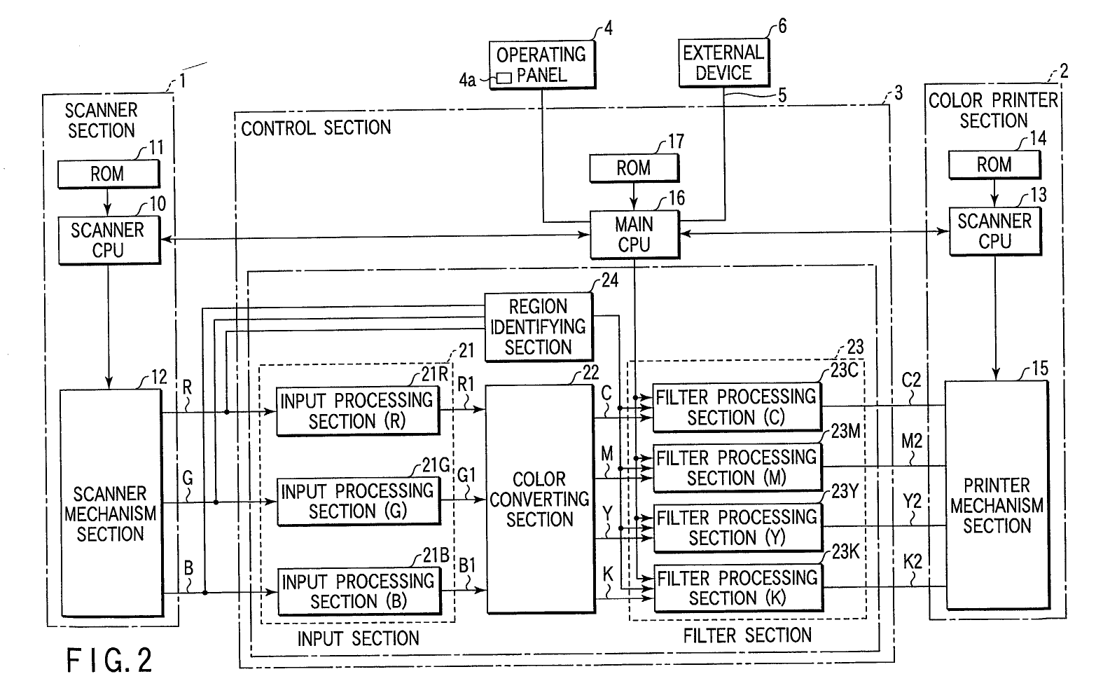

FIG. 1 and FIG. 2 are block diagrams each schematically depicting an internal configuration of an image forming apparatus such as a digital color copying machine for reading a color image on a manuscript, thereby forming the copy image according to the present invention. This image forming apparatus is roughly composed of: a color scanner section 1 as image readout means for reading and input a color image on a manuscript; a color printer section 2 as image forming means for forming a copy image of the inputted color image; a control section 3 that controls the entirety of the image forming apparatus; and an operating panel 4. This apparatus is connected to an external device 6 such as a personal computer via a line 5 such as an LAN.

On the operating panel 4, there is provided a sharpness adjustment key 4a intended to provide a variety of settings, the key indicating sharpness adjustment, for example.

The above scanner section 1 is composed of a scanner CPU 10 that governs the entire control; a ROM 11 having a control program or the like stored therein; a data storage RAM (not shown); and a scanner mechanism section 12.

The scanner mechanism section 12 is composed of: an optical system that reads and scans a manuscript; a moving mechanism that moves this optical system along a manuscript base; a color image sensor that converts a manuscript image guided by the optical system into an image signal of each color; and an image correction section that corrects an image signal outputted from this color image sensor or the like.

The above color printer section 2 is composed of a CPU 13 that governs the entire control; a ROM 14 having a control program or the like stored therein; a data storage RAM (not shown); and a printer mechanism section 15.

The printer mechanism section 15 is composed of printers that carry out printing based on image data (Y, M, C, K) on each color decomposed by color at an image processing section 18 described later. The printers each comprise: a photo-sensor drum as an image carrier; an electrification device that electrifies a surface of the photo-sensor drum; and an exposure device that has a semiconductor laser oscillator whose light emission is controlled based on image data (Y, M, C, K) on each color decomposed by color and forms a hidden electrostatic image at the photo-sensor drum; a developing device that develops the hidden electrostatic image on the photo-sensor drum by a toner image; a carrying mechanism that carries out paper as an image forming medium; a transcription device that transcribes the toner image on the photo-sensor drum onto the paper carried by this carrying mechanism; and a fixer device that thermally fixes the toner image transcribed onto the paper by the transcription device or the like.

The above control section 3 is composed of: a main CPU 16 that governs the entire control; an ROM (read only memory) 17 having a control program and a filter coefficient set or the like stored therein; an image processing section 18 applying a color conversion or filtering process to image data decomposed by color into red (R), green (G), and blue (B) inputted from the scanner section 1, thereby outputting print data to the color printer section 2. A ROM 17 stores a group of a basic coefficient set and a differential coefficient set as a filter coefficient set (described later).

In addition, although not shown, the above control section 3 comprises: a RAM that temporarily stores data; an NVRAM (nonvolatile random access memory back up in battery: nonvolatile RAM) that is a nonvolatile memory a shared RAM used for making bi-directional communication between a main CPU 16 and a printer CPU 13; a page memory having a region capable of storing image information for a plurality of pages and formed so as to store data obtained by compressing image information from the scanner section 1 for each page; and a page memory control section that stores or reads out image information relevant to this page memory.

The above image processing section 18 is composed of: an input section 21 as image data input means; a color converting section 22 as color converting means; a filter section 23; and a region identifying section 24.

The input section 21 consists of input processing sections 21R, 21G, and 21B for each color having inputted thereto image data decomposed by color into red (R), green (G), and blue (B) from the scanner section 1.

The color converting section 22 converts image data on R, G, and B from the input section 21 into data on cyan (C), magenta (M), yellow (Y), and black (K).

The filter section 23 switches a set of filter coefficients used for a filtering process by a region identifying signal from the region identifying section 24 relevant to each of image data on Y, M, C, and K outputted from the color converting section 22, thereby carrying out the filtering process.

The filter section 23 carries out filtering process such as noise elimination/edge enhancement. This section is composed of: filtering processing sections 23Y, 23M, 23C, and 23K that carry out filtering processing for each of the image data on Y, M, C, and K.

The region identifying section 24 identifies whether a target pixel is part of a character or part of a photograph, identifies type of the corresponding manuscript based on image data decomposed by color from the scanner section 1, and outputs a region identifying signal as the identification result.

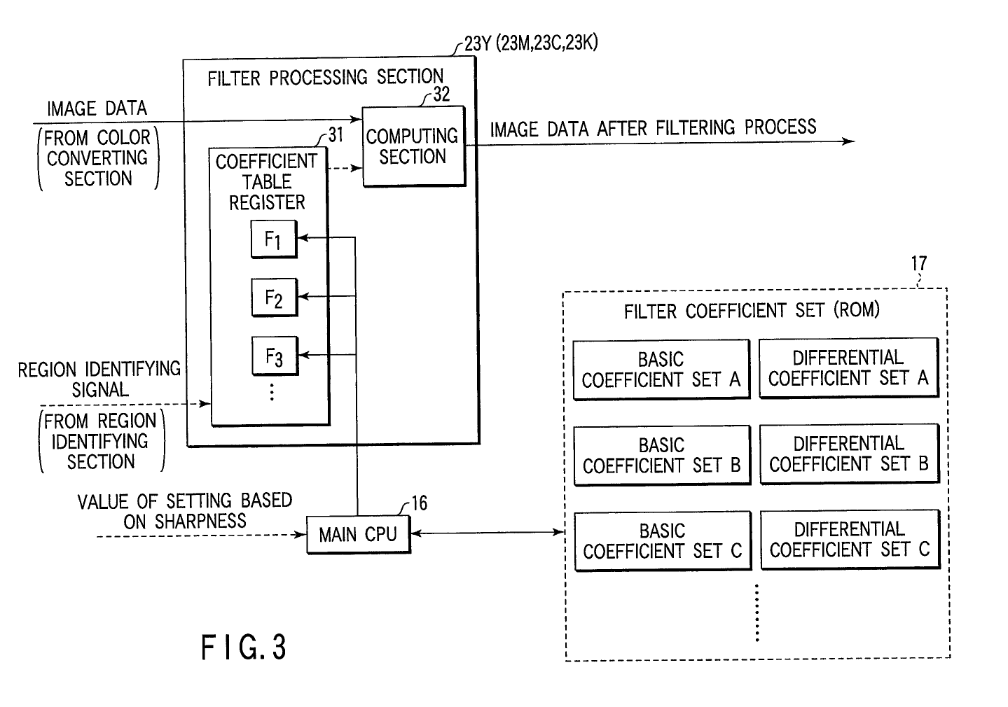

FIG. 3 shows a configuration of a filter processing section 23Y (23M, 23C, and 23K) and a flow of data during copying operation.

A filter processing section 23Y is composed of a coefficient table register 31 and a computing section (correcting section) 32.

The coefficient table register 31 is composed of a plurality of registers F1, . . . . Filter coefficients selectively read out from the ROM 17 are preset to these registers F1, . . . based on the adjustment values (set values) by a main CPU 16.

For example, when an adjustment value (manuscript mode, sharpness adjustment, or enlargement/reduction and the like) is inputted by the sharpness adjustment key 4a of the operating panel 4, and a copy execution key of the copying machine is pressed, the main CPU 16 selects a group of a basic coefficient set and a differential coefficient set from a filter coefficient set stored in the ROM 17 according to the inputted value.

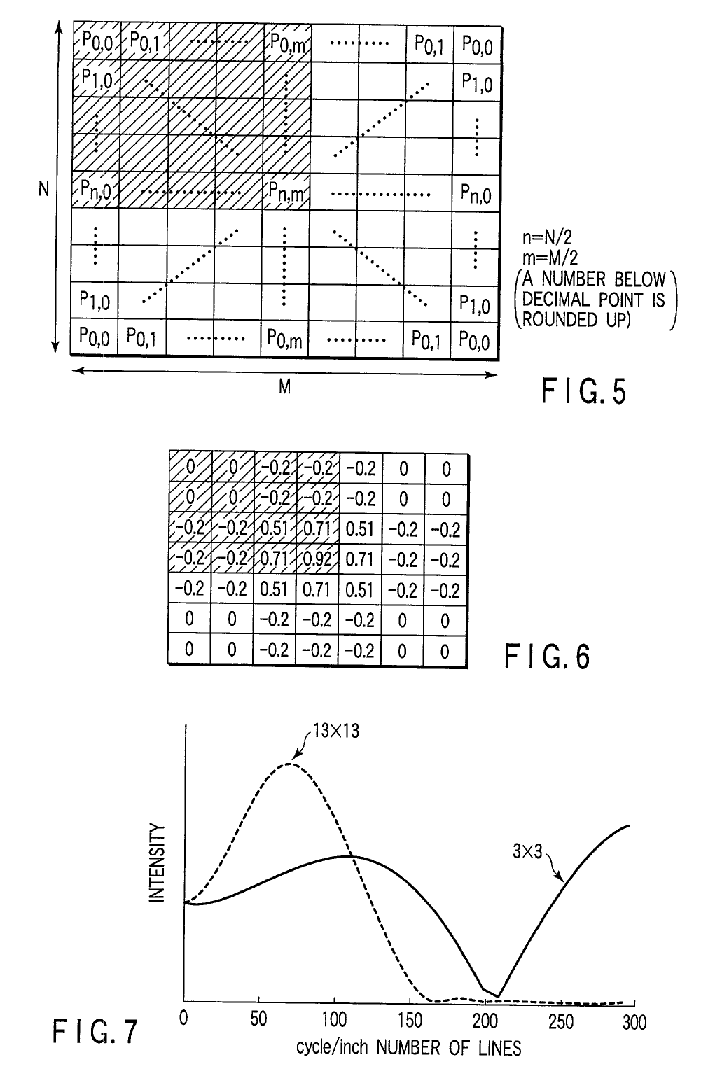

Here, the filter coefficient set stored in the ROM 17 is held by coefficients that correspond to about ¼ of a total number of filter coefficients (corresponding to a portion shaded in FIG. 5). A filter coefficient obtained from a gain computed according to a group of the selected coefficient set and the adjustment value caused by the sharpness adjustment key 4a of the operating panel 4 is incorporated in a register F1. At this time, a coefficient value indicating a number that corresponds to that shaded in FIG. 5 is written.

Similarly, a coefficient set is selected by the main CPU 16, a filter coefficient is computed from gain computation, and the computation results are written sequentially in registers F2, F3, . . . .

A plurality of registers F1, . . . are provided, and are switched according to a region identifying signal that corresponds to image data inputted to a filter processing section 23Y.

For example, when a region identifying signal is “character”, processing is carried out by using a coefficient table register F1. In the case of “photograph”, processing is carried out by using a coefficient table register F2. In the case of “printing paper/photograph manuscript”, processing is carried out by using a coefficient table register F3. A filtering process suitable to each image region can be carried out by this process. That is, an image density signal of a target pixel, yellow, as image data is corrected by using a filter value of the corresponding coordinate system of the filter selected based on the above region identifying signal.

A flow of computing a coefficient table register value from a basic filter and a differential filter is as follows.

1. Gain Computation

gain=A×t+tx (1)

A: Adjustment value caused by the sharpness adjustment key 4a of the operating panel 4

t: Gain control value

tx: Gain reference value

In this gain computation formula, an input value of the sharpness adjustment key 4a is defined as a variable, a gradient is defined as “t”, and 0 intercept is defined as “tx”. In this manner, “t” represents a quantity of change in gain per step of the sharpness adjustment key 4a; “tx” is obtained as a gain value that is a reference in the case where the sharpness adjustment key 4a is not inputted.

2. Computation of Filter Coefficient Value FLT [i]

FLT[i]=FB[i]+gain×FD[i] (2)

i: Serial number of filter coefficient

FB[i]: Basic filter coefficient

FD[i]: Differential filter coefficient

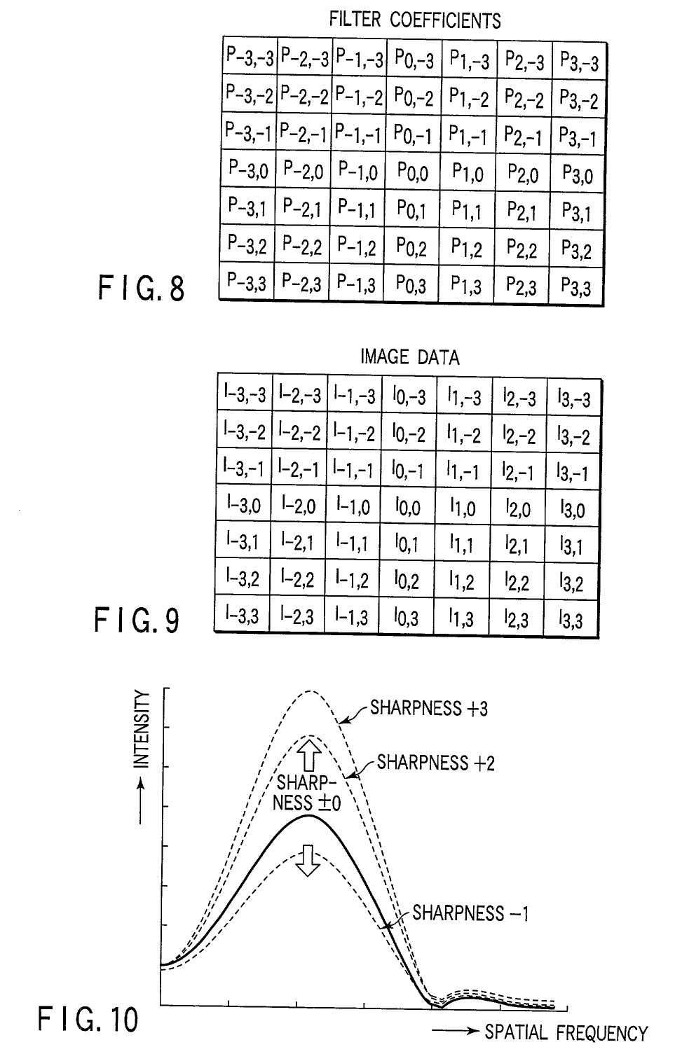

The serial number of the above filter coefficient is assigned for the convenience of computation. For example, in the case of FIG. 8, unique numbers are assigned sequentially from the upper left to the right. When the assigned number reaches the right end, unique numbers are assigned sequentially from the left end to the right end of the next stage.

As shown in FIG. 5, a design is made such that the frequency characteristic curves of a group of the basic filter and differential filter are substantially equal to each other, and only the intensities are different (the peak frequencies are the same, and the degrees of enhancement are different). Doing this makes it possible to obtain a filter coefficient with its changed intensity without changing the shape of frequency response through computation.

Therefore, it is possible to set a filter with its intensity without increasing a redundant filter coefficient table in the ROM 17. High image quality can be achieved by carrying out processing while switching is made to a filter suitable according an image region.

The image data processed by the filter processing section 23 is converted into a printer output signal after carrying out processing such as Chinese ink printing or γ-correction, and is delivered to the color printer section 2.

Therefore, when an image contrast is enhanced by the filtering process, if a manuscript image has a net spot structure, it may causes an occurrence of moire. Because of this, it is required to provide characteristics such that a spatial frequency component is weakened, the component falling into the number of lines mainly used for a print manuscript. In order to meet this requisition, a filter size is increased, whereby a design can be made such that contrast is enhanced for each finer frequency bandwidth.

As has been described above, when a filter coefficient set is held by the ROM 17, a filter coefficient structure is symmetrically provided as shown in FIG. 5 without storing all the coefficients, thereby making it possible to reduce an amount of data to about ¼. FIG. 6 shows an example when the filter size is 7×7, and data is stored at a 4×4 portion shaded in the figure.

In this way, the filter size is increased, whereby the degree of freedom for a filtering process can be increased.

FIG. 7 shows frequency characteristics at a 3×3 filter size and a 13×13 filter size when the filter size is inputted at 600 dpi (dot per inch).

In the case of 13×13, a design is made such that the vicinity of 80 cpi is enhanced, and a frequency component higher than 170 cpi is eliminated. However, in the case of 3×3 size, only one frequency component can be controlled. Thus, a design is made such that the vicinity of 200 cpi can only be eliminated. This is because a larger number of frequency points can be controlled with an increase in filter size.

The above computing section 32 will be described with reference to FIG. 4 by way of example when the filter size is 7×7.

The above computing section 32 is composed of: line memories 41a to 41f and a filter processing/computing section 43.

The line memories 41a to 41f sequentially delay image data one by one lines from the color conversion section 22, and stores the data in amount that corresponds to six lines.

The filter processing/computing section 42 executes filter computation for image data in amount that corresponds to six lines from these line memories 41a to 41f, image data in amount that corresponds to the newest one line, and target image data by 16 (4×4) filter coefficients (KREG1 to KREG16) selected according to a region identifying signal by the coefficient table register 31 in FIG. 3.

When the target image is defined as I_{(0,0)}, the filter computation formula is established as follows.

$${I}^{′} ( 0 , 0 ) = {\sum }_{i = - 3}^{i = 3} {\sum }_{j = - 3}^{j = 3} {P}_{i , j} \times {I}_{i , j}$$

where I′_{(0,0)} denotes data after filter processing, and meets P_{i, j}=P_{|i|, |j|} (symmetry of filter coefficient)

Now, a description of sharpness adjustment will be given below.

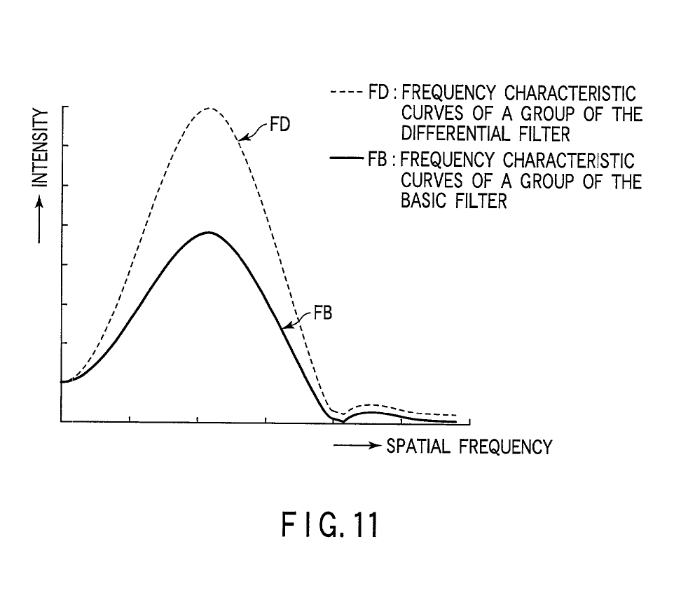

For example, assume that sharpness adjustment is set by the sharpness adjustment key 4a of the operating panel 4, whereby a gain controlled filter coefficient is computed by formulas (1) and (2). As shown in FIG. 10, a filter coefficient is computed such that intensity is changed according to sharpness adjustment without the shape of frequency characteristics (frequency bandwidth to be enhanced/restrained).

In such a state, a manuscript is placed on a manuscript base, and the operating panel 4 instructs a user to start copying. Then, the manuscript image placed on the manuscript base is read by the scanner section 1, and the read image is outputted to the input section 21 of the image processing section 18.

In this manner, the input section 21 outputs the inputted image data decomposed by color into red (R), green (G), and blue (B) to the color converting section 22. The color converting section 22 converts the supplied RGB image data into data on cyan (C), magenta (M), yellow (Y), and black (K), and outputs the converted data to the filter processing section 23. The filter processing section 23 applies processing such as noise elimination/edge enhancement to the supplied image data on Y, M, C, and K based on the above computed filter coefficient. Further, after carrying out processing such as Chinese ink printing or γ-correction, the processed data is converted into a printer output signal, and the converted signal is outputted to the color printer section 2.

As described above, the filter size is increased, and the degree of freedom for filtering process is increased. A sufficient increase in filter size makes it possible to design a filter such that the contrast is enhanced or damped in a frequency region by finer bandwidth.

In addition, a filter coefficient set stored in a ROM as storage means is configured in size that is ¼ of the filter size. namely, as a method for storing a coefficient of a large filter size, when a filter is divided into four quadrants, symmetry is provided to each coefficient that belongs to one of these quadrants such that coincidence is obtained when the other adjacent quadrants are returned, whereby data stored in memory in quantity corresponding to the one quadrant (including the remaining portion if the size cannot be divided into four sections), thereby reducing a storage capacity.

Further, each filter coefficient set stored in the ROM is divided into two types of basic filter coefficient set and differential filter coefficient set. When the CPU writes each filter coefficient into the filter coefficient table, filter setting with its changed intensity is provided by using the basic coefficient set and differential coefficient set provided by the ROM, based on a gain computed from the value of sharpness adjustment (setting) on the operating panel.

In addition, a plurality of filter coefficient table registers are provided as hardware, and a filter coefficient table used according to a region identifying signal can be switched.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An image processing apparatus comprising:
a color converting section that converts three primary colors of colors supplied for each pixel of a manuscript image into plural types of color data related to a complementary color;
a region identifying section that identifies a region for each pixel based on the three primary colors of the colors supplied for each pixel of the manuscript image;
a setting section that sets a value of sharpness setting;
a storage section that stores a filter coefficient that consists of a basic coefficient and a differential coefficient for each value of sharpness setting;
a generating section that reads out from the storage section the filter coefficient based on the value of the setting caused by the setting section, and generates plural types of matrix shaped filters, each of which corresponds to an area identified by the region identifying section according to the read out filter coefficient;
a selecting section that selects one of the plural types of matrix shaped filters generated by the generating section according to the identification result from the region identifying section; and
a filter section that subjects color data acquired from the color converting section to a filtering process by using the matrix shaped filter selected by the selecting section.

2. An image processing apparatus according to claim 1, wherein three primary colors of the color is red (R), green (G), and blue (B), and plural types of color data are cyan (C), magenta (M), yellow (Y), and black (K).

3. An image processing apparatus according to claim 1, wherein a filter coefficient stored in the storage section is configured in size that corresponds to ¼ of the filter size.

4. An image processing method of such type comprises the steps of:
converting three primary colors of colors supplied for each pixel of a manuscript image into plural types of color data related to a complementary color;
identifying a region for each pixel based on the three primary colors of the colors supplied for each pixel of the manuscript image;
reading out the filter coefficient based on the value of sharpness setting based on the filter coefficient that consists of a basic coefficient and differential coefficient for each value of sharpness setting stored in the storage section; and
generating plural types of matrix shaped filters, each of which corresponds to the region identified according to the read out filter coefficient;
selecting one of the plural types of matrix shaped filters generated according to the identification result of the region; and
subjecting color data acquired from the color converting section to a filtering process by using the matrix shaped filter selected.

5. An image processing method according to claim 4, wherein three primary colors of the color is red (R), green (G), and blue (B), and plural types of color data are cyan (C), magenta (M), yellow (Y), and black (K).

6. An image processing method according to claim 4, wherein a filter coefficient stored in the storage section is configured in size that corresponds to ¼ of the filter size.

7. An image forming apparatus comprising:
image readout means for reading three primary colors of colors for each pixel of a manuscript image;
a color converting section that converts the three primary colors of colors read out by the image readout means into plural types of color data related to complementary colors;
a region identifying section that identifies a region of each pixel based on the three primary colors of the colors supplied for each pixel of the manuscript image;
a setting section that sets a value of sharpness setting;
a storage section that stores a filter coefficient that consists of a basic coefficient and a differential coefficient for each value of sharpness setting;
a generating section that reads out from the storage section a filter coefficient based on the value of setting caused by the setting section, and generates plural types of matrix shaped filters that corresponds to a region identified by the region identifying section according to the read out filter coefficient;
a selecting section that selects one of plural types of matrix shaped filters generated by the generating section according to the identification result from the region identifying section;
a filter section that subjects color data acquired from the color converting section to a filtering process by using the matrix shaped filter selected by the selecting section; and
image forming means for forming an image on an image forming medium based on color data outputted from the filter section.

8. An image forming apparatus according to claim 7, wherein three primary colors of the color is red (R), green (G), and blue (B), and plural types of color data are cyan (C), magenta (M), yellow (Y), and black (K).

9. An image forming apparatus according to claim 7, wherein a filter coefficient stored in the storage section is configured in size that corresponds to ¼ of the filter size.

10. An image processing apparatus comprising:
a converting section that converts each input pixels of two-dimensional images in a main scanning direction and a sub-scanning direction each into an image density signal;
an identifying section that identifies a character region or a photograph region and the like based on an image density signal in units of target pixels from this converting section;
a setting section that sets a sharpness level;
a storage section that stores a filter coefficient that consists of a basic coefficient and a differential coefficient for each level of the sharpness;
a generating section that reads out from the storage section the filter coefficient based on the value of setting caused by the setting section, and generates plural types of matrix shaped filters that correspond to the identification results obtained by the identifying section for said each read out filter coefficient;
a selecting section that selects one of plural types of matrix shaped filters generated by the generating section according to the identification results from the identifying section; and
a correcting section that corrects an image density signal from the converting section by using a filter value in the corresponding coordinate system of the filter selected by the selecting section.

11. An image processing apparatus comprising:
plural converting sections that convert each input pixels of two-dimensional images in a main scanning direction and a sub-scanning direction each into an image density signal of a respective one of a variety of colors;
an identifying section that identifies a character region or a photograph region and the like based on an image density signal in units of these target pixels from these converting sections;
a setting section that sets a sharpness level;
a storage section that stores a filter coefficient that consists of a basic coefficient and a differential coefficient for each level of the sharpness;
plural generating sections that read out from the storage section the filter coefficient based on the value of setting caused by the setting section, and generate plural types of matrix shaped filters that correspond to the identification results obtained by the identifying section by a respective one of a variety of colors according to this readout filter coefficient;
a selecting section that selects a respective one of plural types of matrix shaped filters generated by the generating section according to the identification results from the identifying section; and
plural correcting sections that correct an image density signal of each of the variety of colors from the converting section by using a filter value in the corresponding coordinate system of the filter selected by the selecting section.
